(19) United States
(12) Patent Application Publication
(10) Pub. No.: US 2003/0126524 A1
(43) Pub. Date: Jul. 3, 2003

(54) Semiconductor storage unit

(75) Inventors: Yoji Kashihara, Tokyo (JP); Shigeki Ohbayashi, Tokyo (JP); Akira Hosogane, Tokyo (JP); Motomu Ukita, Tokyo (JP)

Correspondence Address: MCDERMOTT, WILL & EMERY, 600 13th Street, N.W., WASHINGTON, DC, 20005-3096, US

(73) Assignee: Mitsubishi Denki Kabushiki Kaisha

(21) Appl. No.: 10/223,349

(22) Filed: Aug. 20, 2002

(30) Foreign Application Priority Data
Dec. 28, 2001 (JP) 2001-400949
Feb. 22, 2002 (JP) 2002-45942

(51) Int. Cl. G11C 29/00; G01R 31/28

(52) U.S. Cl. 714/718; 714/727

(57) ABSTRACT

In a chip with pads provided on four sides, I/O defects of the chip can be determined with test probes applied to two sides of the chip. A semiconductor storage unit has data pads which input/output data arranged on predetermined two sides, and control pads which input/output control data arranged on other two sides. The unit includes test circuits connected in series and connected to a corresponding data pads and has a register circuit. The register circuit holds and outputs inputted data based on a test signal. Storage elements stores data and are connected to a corresponding test circuit. At the time of testing, the elements store the data from a predetermined data pad and transmitted to a predetermined test circuit. The register circuit reads the data in the corresponding storage element and outputs the data from the predetermined data pad via other register circuit.

### BACKGROUND OF THE INVENTION

1. Field of the Invention

The present invention relates to a test of a semiconductor storage unit which performs multi-bit inputs and outputs.

2. Description of the Background Art

In chips of semiconductor storage units that performs multi-bit inputs and outputs (such as x36, x72 products), chips are connected to external substrates and the number of pins that perform data inputs and outputs increases. Consequently, in recent years, pads for connecting pins and a chip are frequently arranged on four sides of the chip. In such event, in general, it is the popular practice to arrange data pads on two sides of the chip and address/control pads on the remaining two sides.

A problem when pads are arranged on four sides lies in an increase of wafer test cost. In general, in the wafer test, the test time is reduced by simultaneously testing a plurality of chips. This precisely achieves the reduction of test cost. However, applying test needles (probes) to all the four sides of a chip cannot test a plurality of chips simultaneously. This greatly increases the test cost. Recently, it is a general practice to simultaneously measure many chips (for example, 32 pieces). Consequently, for example, if 32 chips cannot be simultaneously measured, the test time increases 10 times at a stretch and the test cost will increase 32 times, if simply calculated. This is the problem which cannot be ignored.

Japanese Laid-open Patent Publication No. 11-317100 discloses a technique for avoiding the above-mentioned problem. This document proposes a method which reduces the number of I/Os subject to measurement by degenerating, that is, reducing 9 pieces of output data (I/O data) to one. Since 9 pieces of I/O data are degenerated to one piece, x36 product chips can be tested as x4 product chips. Since the number of data pads can be greatly reduced, pads to which probes are applied can be collected and arranged into two sides, and consequently, it is only needed to apply probes to pads only exiting on two sides of a chip. According to this configuration, a large number of chips can be simultaneously measured.

The method proposed by the above-mentioned document causes the degree of freedom of saving redundancy to decrease because the data is degenerated. That is, by this method, even if defective I/O is detected, it is unable to find out which I/O is defective.

In order to save defective I/Os, in general, a redundancy circuit is provided. The redundancy circuit is, for example, one or more circuits installed with the configuration same as the I/O and is used for substitution of defective I/Os. When the defect detected by the above-mentioned method is saved by the redundancy circuit, all the corresponding addresses of nine I/Os must be replaced simultaneously. Since the number of redundancy circuits is limited, for example, if there provided is redundancy for two addresses and if there is one each defect in different addresses of each I/O, and if there are defects in three or more I/Os, saving is disabled. Even in this kind of defect, if redundancy can be independently replaced for every I/O, saving is possible. This is expressed as a difference of yield. In particular, recently, because the ratio of redundancy-saved products has been increased, the difference of yield due to the degree of freedom of redundancy circuits tends to increase. To lower the yield, it is expressed as an increase of chip cost.

### SUMMARY OF THE INVENTION

It is an object of the present invention to reduce the number of sides with test probes applied to two in a chip with pads provided on four sides, to specify I/O defects.

It is another object of the present invention to detect whether internal signals are applied or not when I/O defects are specified.

A semiconductor storage unit according to the present invention includes a plurality of data pads which input and output data arranged on predetermined two sides and a plurality of control pads which input and output control data arranged on other two sides. The semiconductor storage unit further includes a plurality of test circuits connected in series, each of which is connected to a corresponding data pads of the plurality of data pads and has a register circuit which holds and outputs inputted data based on a test signal; and a plurality of storage elements, each of which stores data and is connected to a corresponding test circuit of the plurality of test circuits. At the time of testing the semiconductor storage unit, the plurality of storage elements store the data inputted from a predetermined data pad of the plurality of data pads and transmitted to a predetermined test circuit. The register circuit reads the data stored in the corresponding storage element and outputs the data from the predetermined data pad via other register circuit of the plurality of test circuits connected in series.

According to the present invention, sides of the chip, to which test probes are applied are only two, and the number of pads with test probes applied is remarkably reduced. Consequently, a plurality of semiconductor storage units can be simultaneously wafer-tested and it is possible to identify which I/O is defective. Furthermore, the data stored in the storage element is read to a register circuit of the corresponding test circuit and is outputted from a specific data pad via a register circuit of a plurality of test circuits connected in series. According to this configuration, the number of sides to which test probes are applied is reduced to two only and the number of pads with the test probes applied is remarkably reduced. Consequently, a plurality of semiconductor storage units can be simultaneously wafer-tested and it is also possible to identify which I/O is defective.

The semiconductor storage unit according to the present invention includes a plurality of data pads which are arranged on predetermined two sides and which input and output data; a plurality of control pads which are arranged on other two sides different from the predetermined two sides and which input and output control data; and a control circuit which controls operations of the semiconductor storage unit. The control circuit includes an internal circuit, connected to at least one of the control pads, which operates the semiconductor storage unit based on the control signal applied to the control pad, power supply which supplies current, and a current generating circuit which feeds the current supplied from the power supply to at least one of the control pads when a test signal is of the test mode level.

Since the current supplied from the power supply to one of the control pads when the test signal is of the test mode level, it is possible to confirm even from the outside of the semiconductor storage unit that the test mode operation based on the test signals is normally carried out by detecting this current.

### BRIEF DESCRIPTIO OF THE DRAWINGS

These and other object and features of the present invention will become clear from the following description taken in conjunction with the preferred embodiments thereof with reference to the accompanying drawings, in which:

FIG. 1 shows a top view of a chip of a semiconductor storage unit of x72 configuration;

FIG. 2 is a block diagram of a pad peripheral circuit of chips according to embodiment 1;

FIG. 3 is a block diagram of an output test circuit;

FIG. 4 is a block diagram of an output test circuit;

FIG. 5 is a block diagram of an input test circuit;

FIG. 6 is a block diagram of an input test circuit;

FIG. 7 is a block diagram of an input test circuit;

FIG. 8 is a block diagram of an input test circuit;

FIG. 9 is a diagram of test waveforms when the first write method is adopted;

FIG. 10 is a diagram of test waveforms of the write portion when the second write method is adopted;

FIG. 11 is a diagram of a pad peripheral circuit of chips according to embodiment 2;

FIG. 12 is a block diagram of a typical boundary scan register;

FIG. 13 is a block diagram of another pad peripheral circuit according to embodiment 2;

FIG. 14 is a block diagram of an output boundary scan register;

FIG. 15 is a block diagram of an input boundary scan register;

FIG. 16 is a diagram of test waveforms at the time of writing;

FIG. 17 is a diagram of test waveforms at the time of reading;

FIG. 18 is a block diagram of a pad peripheral circuit equipped with a boundary scan register used both for I/O;

FIG. 19 is a block diagram of a simplified configuration of the boundary scan register used both for I/O;

FIG. 20 is a block diagram of a pad peripheral circuit equipped with the boundary scan register used both for I/O;

FIG. 21 is a block diagram of the boundary scan register used both for I/O;

FIG. 22 is a diagram of a test waveform at the time of writing;

FIG. 23 is a diagram of a test waveform at the time of reading;

FIG. 24 is a block diagram of a pad peripheral circuit when data I/O pad DQ2 is used for a probe-applied pad;

FIG. 25 is a block diagram of an example of the configuration of the boundary scan register;

FIG. 26 is a block diagram of one example of the boundary scan register;

FIG. 27 is a top view of a chip of the semiconductor storage unit with pad intervals reduced;

FIG. 28 is a block diagram of a control circuit according to embodiment 4;

FIG. 29 is a block diagram of another configuration of a micro-current generating circuit;

FIG. 30 is a block diagram of the configuration when the micro-current generating circuit is equipped to a control circuit which is activated by high-level control voltage;

FIG. 31 is a block diagram of the control circuit according to embodiment 5;

FIG. 32 is a truth value table of the relationship between test signal and reversed clock signal and operations of two micro-current generating circuits;

FIG. 33 is a block diagram of the control circuit according to embodiment 6;

FIG. 34 is a block diagram of the specific configuration of D flip-flop;

FIG. 35 is a truth value table of the relationship between input and output of D flip-flop; and

FIG. 36 is a timing chart of operations of the control circuit.

### DETAILED DESCRIPTION OF THE PREFERRED EMBODIMENTS

Referring now to the drawings attached, preferred embodiments of the present invention will be described as follows.

(Embodiment 1)

To a chip of a semiconductor storage unit handled in embodiment 1, it is assumed that data I/O pads for performing data I/O are arranged on four sides of the chip. The number of pads used for data I/O are, for example, 72 pieces. The chip equipped with this kind of pads is also referred to as “a chip of a semiconductor storage unit of x72 configuration”. In the present specification, the “semiconductor storage unit” is primarily intended for a static random access memory (SRAM), but may also be applied to a dynamic random access memory (DRAM).

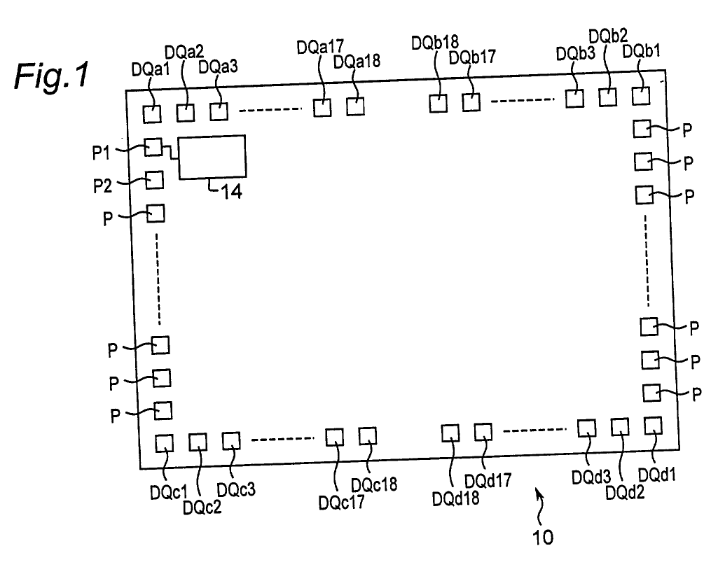

FIG. 1 shows a top view of chip 10 of the semiconductor storage unit of x72 configuration. Chip 10 has 72 pieces of data I/O pads DQ (DQa1-18, DQb1-18, DQc1-18, DQd1-18) on the opposite two sides and has address/control pad P (P1, P2, . . . ) on remaining two opposite sides. To the address/control pad P, the control data related to control of chip 10 is inputted and outputted. That is, to control pad P1, control circuit 14 is connected. The control circuit 14 will be described in detail in embodiments 4 through 6. In each of the data I/O pas DQ groups (DQa, DQb, DQc, DQd), at least one pad comes in contact with either of the two sides where address/control pad P exits. Specifically, data I/O pads DQa1, DQb1, DQc1, DQd1 come in contact with two sides where address/control pad P exists.

The feature of the present invention is that in the performance test of chips concerning data I/O (chip test), 18 pieces of I/O data of the group can be serially outputted from one pad for each group of DQ a through d without degenerating the test data. By entering and outputting the data from the pad in contact with the side of address/control pad P (that is a square pad), it is possible to easily carry out probe application and at the same time to reduce the number of pads utilized for the test.

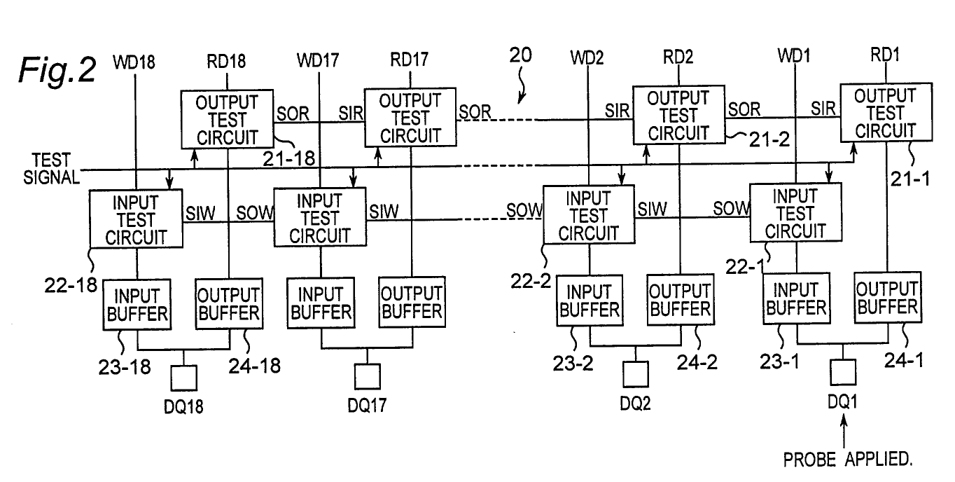

FIG. 2 is a block diagram showing the configuration of circuit 20 around the data I/O pad of chip 10 (FIG. 1) according to embodiment 1 (hereinafter called the “pad peripheral circuit”). As illustrated, the test needle (probe) is applied to data I/O pad DQ1. Note that data I/O pad DQ1 corresponds to pad DQ1a, DQb1, DQc1, DQd1 in contact with any of two sides where address/control pad P exists.

Referring now to FIG. 2, the configuration of pad peripheral circuit 20 will be described. In the following description, n is any integer from 1 through 18. Pad peripheral circuit 20 is equipped with data I/O pad DQn, output test circuit 21-n, input test circuit 22-n, input buffer 23-n, and output buffer 24-n. In addition, pad peripheral circuit 20 comprises write data bus WDn for inputting the data to be written in the memory core (not shown) as a storage cell, and read data bus RDn for reading the data from the memory core (not shown). The output SOW of input test circuit of I/O 22-k (k: integer from 1 to 17) is connected to input SIW of adjacent input test circuit 22-(k+1) to for a serial path. Similarly, output SOR of output test circuit 21-k (k: integer from 1 through 17) for I/O is connected to input SIR of adjacent output test circuit 22-(k+1) to form a serial path.

Referring now to FIG. 2, reading of the data from chip 10 of the semiconductor storage unit in normal use is carried out by giving signals from read data bus RDn to output buffer 24-n and by outputting from data I/O pad DQn. In addition, writing of the data to chip 10 (FIG. 1) of the semiconductor storage unit is carried out by receiving of input buffer 23-n the data via data I/O pad DQn and giving the output of input buffer 23-n to write data bus WDn.

When chip 10 (FIG. 1) of the semiconductor storage unit is tested, a plurality of test mode signals Test are given to output test circuit 21-n/input test circuit 22-n, and functions of the present invention are achieved. Now, this will be specifically explained as follows:

In the present embodiment, output test circuit 21-1/input test circuit 22-1 applied to data I/O pad DQ1 with probes applied differs from output test circuit 21-n/input test circuit 22-n (n: integer from 2 through 18) applied to data I/O pad DQn (n: integer from 2 through 18) with no probe applied.

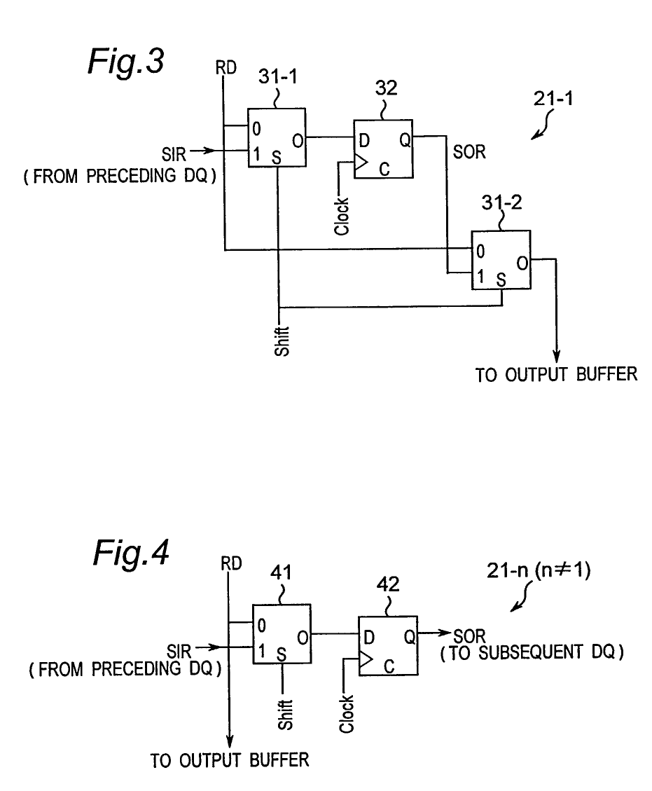

First of all, output test circuit 21-1 is explained. FIG. 3 is a block diagram showing the configuration of output test circuit 21-1. Output test circuit 21-1 includes selector circuits 31-1, 31-2, and register circuit 32.

In the block of selector circuits 31-1 and 31-2, reference character S denotes test signal (select input) Shift for controlling the test mode operation, numeral 0 denotes the input selected when S=0, numeral 1 is the input selected when S=1, and reference character O denotes the output. In the block of register circuit 32, reference character C denotes the input of test signal (Clock) for controlling the test mode operation, reference character D denotes the data input and reference character Q denotes the data output. As illustrated, when select input signal Shift is 0, the regular reading operation takes place. Selector circuit 31-2 receives the data from read data bus RD and output the data to output buffer 24-1 (FIG. 1). Since select input signal Shift is 0, selector circuit 31-2 does not receive the signal that has passed selector circuit 31-1 and register circuit 32. On the other hand, when select input signal Shift is 1, the test operation takes place. Selector circuit 31-1 receives from adjacent output test circuit 21-2 (FIG. 1) and outputs the data to register circuit 32.

Register circuit 32 holds the data received and output the data held in register circuit 32 based on clock signal (Clock). Selector circuit 31-2 outputs the data received from register circuit 32 to the output buffer.

Next description will be made on the output test circuit other than output test circuit 21-1. FIG. 4 is a block diagram showing the configuration of output test circuit 21-n (n: integer from 2 to 18). This output test circuit includes selector circuit 41 and register circuit 42. The configuration and operation of selector circuit 41 and register circuit 42 are the same as those of selector circuit 31-1 and register circuit 32, respectively. When select input signal Shift is 1, selector circuit 41 receives the data from adjacent output test circuit and outputs the data to register circuit 42. Register circuit 42 holds the data and outputs the data held in register circuit 42 to the adjacent output test circuit based on clock signal (Clock).

Now, the configuration of the input test circuit will be described. The input test circuit is a circuit utilized for data write test. The data write method can be classified into two types, i.e., (1) a method which gives the same data to the pad in parallel and writing the data in 18 I/Os in parallel, and (2) a method which gives 18 separate data to one pad serially and writing this in 18 I/Os independently.

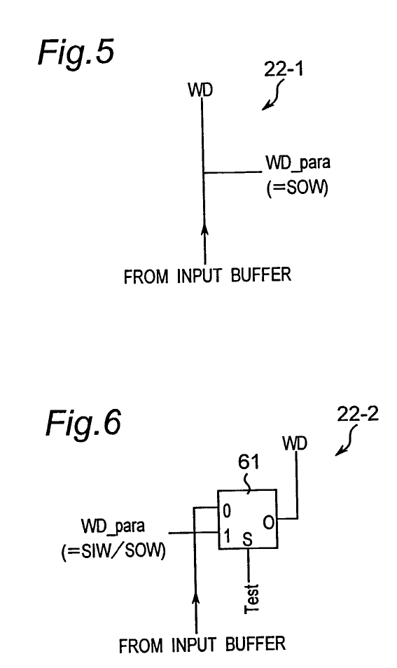

FIG. 5 and FIG. 6 show input test circuit 22-1 and input test circuit 22-n (n: integer from 2 to 18) when the above-mentioned method (1) is adopted. In FIG. 6, input test circuit 22-2 is shown for an example. First of all, FIG. 5 is a block diagram showing the configuration of input test circuit 22-1. In this example, input SIW and output SOW are common and WD_para. Input test circuit 22-1 sends the data sent from input buffer 23 or the data outputted from the adjacent output test circuit to write data bus WD. On the other hand, FIG. 6 is a block diagram showing the configuration of input test circuit 22-2. This input test circuit comprises selector circuit 61. The configuration and operation of selector circuit 61 are same as those of selector circuit 31-1. Selector circuit 61 changes over the data from the adjacent test circuit or from the input buffer on the basis of test mode signal Test and sends the data received to write data bus WD.

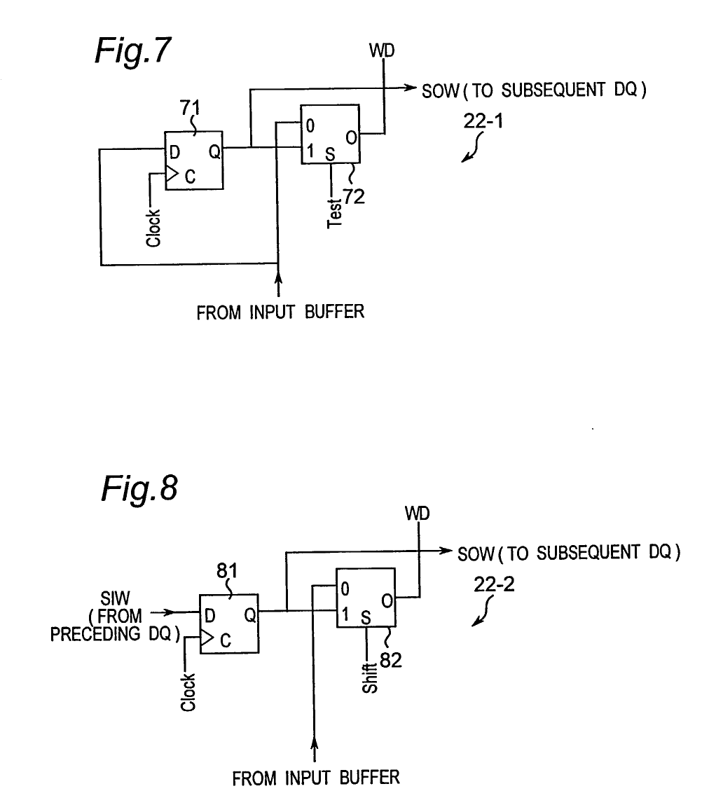

FIGS. 7 and 8 show input test circuit 22-1 and input test circuit 22-n (n: integer from 2 to 18) when the above-mentioned method (2) is adopted. In FIG. 8, input test circuit 22-2 is shown as an example. FIG. 7 is a block diagram showing the configuration of input test circuit 22-1. Input test circuit 22-1 includes register circuit 71 and selector circuit 72. The configuration and operation of these are same as those of register circuit 32 (FIG. 3) and selector circuit 31-1 (FIG. 3), respectively. Furthermore, FIG. 8 is a block diagram showing the configuration of input test circuit 22-2. Input test circuit 22-2 includes register circuit 81 and selector circuit 82. The configuration and operation of these are same as those of register circuit 32 (FIG. 3) and selector circuit 31-1 (FIG. 3), respectively.

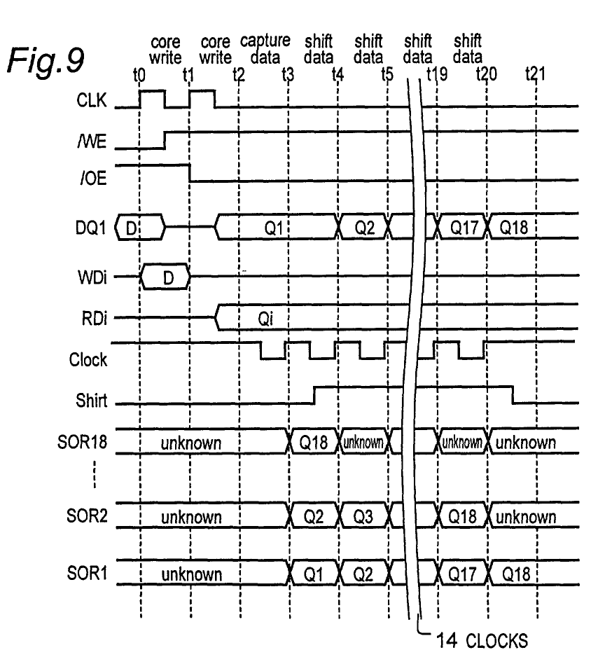

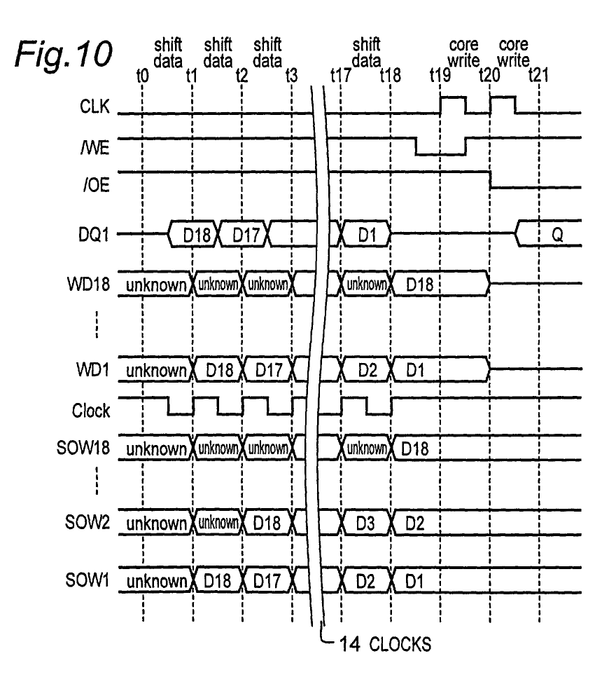

The operation of pad peripheral circuit 20 (FIG. 2) configured as described above is discussed referring to FIGS. 9 and 10. FIG. 9 is a diagram showing test waveforms when write method (1) is adopted. In this diagram, notation to through t21 denote the time. Referring to the waveform of write data bus WDi, writing of data D given to data I/O pad DQ to the memory core (not shown) is executed by varying system clock CLK with write enable signal /WE set to “L” and output enable signal /OE set to “H”. In such event, by holding the test signal to “H”, data D given to data I/O pad DQ1 is transmitted to all the write data buses WD1 through WD18 and the same data D is written to all I/Os between time to and t1.

In the meantime, data reading is executed by varying CLK with /WE set to “H” and /OE to “L”. In such event, between time t1 and t2, read data Q1 through Q18 of each I/O are read to each of read data buses RD1 through RD18. Thereafter, when test signal (Clock) is operated at time t2, the data at each read data bus RD is imported into register output SORi in the output test circuit attached to relevant I/Os. Next, when test signal Shift is varied from “L” to “H” between time t3 and t4, each register is connected serially and a 18-bit-long shift register is formed. Furthermore, every time test signal (Clock) is operated after time t3, the data retrieved is shifted in the direction of output test circuit 21-1 (FIG. 2). As a result, from output SOR1 of output test circuit 21-1 (FIG. 2), that is, from data I/O pad DQ1, the data (Q1 through Q18 shown in FIG. 9) of output test circuits 21-1 through 21-18 (FIG. 2) are outputted successively. In this way, 18 pieces of I/O data can be outputted from one pad. By carrying this out for four groups (DQa through DQd) of the data I/O pad, 72 pieces of I/O data can be outputted from four pads.

FIG. 10 is a diagram showing test waveforms of the written portion when writing method (2) is adopted. The read operation should be the same as in FIG. 9. When writing method (2) is adopted, test signal (Clock) is operated while write data D18 through D1 are being given to data I/O pad DQ1 serially. To be more specific, first of all, operating test signal (Clock) between time t0 and t1 imports data D18 given to data I/O pad DQ1 into register output SOW1 of input test circuit 22-1 (FIG. 2). This data reaches SOW18, that is, write data bus WD18 along the input test circuit. During this period, carrying out shift operation while write data D17 through D1 are being given to data I/O pad DQ1 successively sends the data to a register in the input test circuit attached to each I/O, and data D1 through D18 are set to all the 18 register outputs SOW1 through 18. Since this sets the desired data to each one of WD1 through WD18, write operation to the memory core takes place at time t19 thereafter. The reading operation at time t20 and after is same as that at time t1 and after in FIG. 9. The writing method (1) provides an advantage of simplifying the test as compared to the writing method (2). However, the test of method (2) is more complicated than that of the method (1) and the test time is longer, however optional data can be written to each I/O. Consequently, the degree of freedom of the test is improved.

According to the invention of embodiment 1, since tests are carried out using a pad in contact with two sides of a chip different from the other sides to which the data pad is arranged, the probe is applied to only the two sides, and consequently, a plurality of chips can be simultaneously measured.

(Embodiment 2)

Because in embodiment 1, test dedicated circuits must be added for the input test circuit and the output test circuit for each I/O, a space equivalent to the area for a test dedicated circuit is essential for chips. Therefore, in embodiment 2, a configuration that suppresses an increase of the area for the test dedicated circuit to a minimum will be described.

Almost all semiconductor storage units of recent years, particularly, semiconductor storage units sealed in the Ball Grid Array (BGA), support functions of Joint Test Action Group (JTAG) boundary scan. In order to carry out boundary scan, a mechanism for boundary scan must be provided inside the integrated circuit (IC). That is, at the boundary between inside core logic and I/O pin, boundary scan registers (BSR) must be arranged and connected to form a shift register. In embodiment 2, the circuit used for boundary scan is appropriated and the configuration that can suppress additions of new circuits to a minimum will be described. Note that the BGA package is an IC package that uses solder ball pins as terminals so that easy packaging and the improved packaging density can be achieved. JTAG is a standard of measure of a test interface whose functions can be verified at a board level or chip level in the substrate packaging process. In the following description, functions based on the JTAG standard, JTAG functions, JTAG circuit, etc. will be referred. Lastly, boundary scan can execute tests by entry of test codes and responses to these by controlling the shift register. It is called boundary scan because it scans the boundary between the device inside and the outside.

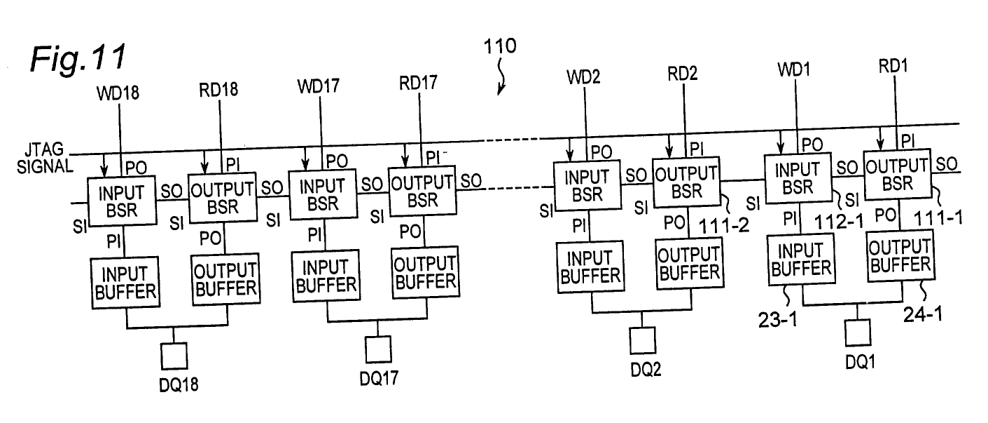

FIG. 11 is a block diagram showing circuit (hereinafter called the “pad peripheral circuit”) 110 around the data I/O pad of chip 10 (FIG. 1) according to embodiment 2. Chip 10 (FIG. 1) according to embodiment 2 includes the JTAG functions.

The configuration of pad peripheral circuit 110 is extremely similar to the configuration of pad peripheral circuit 20 (FIG. 2). Consequently, appropriating the JTAG can achieve a configuration that can embody the present invention while the addition of new circuits is kept to a minimum.

What differs as to pad peripheral circuit 110 from pad peripheral circuit 20 (FIG. 2) is that, to take data I/O pad DQ1 for an example, input boundary scan register 112-1 is installed between input buffer 23-1 and write data bus WD1, and output boundary scan register 111-1 is inserted between output buffer 24-1 and read data bus RD1. This is the same as for each data I/O pad DQ. As described above, output SO and input Si of adjacent boundary scan registers are connected in series to form a shift register as a whole.

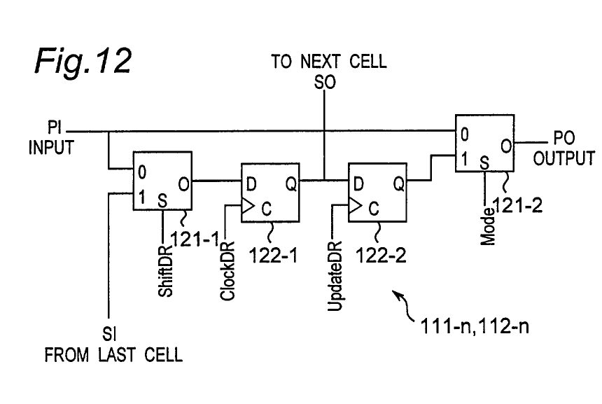

FIG. 12 is a block diagram showing the configuration of typical boundary scan registers 111-n, 112-n (n: integer from 1 through 18). This configuration is common to both input and output boundary scan registers. Signals ShiftDR, ClockDR, Update DR, and Mode shown in FIG. 12 are signals generated in the JTAG circuit. In addition, in input boundary scan register 112-n, input PI and output PO correspond to signals from input buffer and to write data bus WD. In output boundary scan register 111-n, input PI and output PO correspond to signals from read data bus RD and to output buffer. Reference character SI denotes a serial input and reference character SO denotes a serial output.

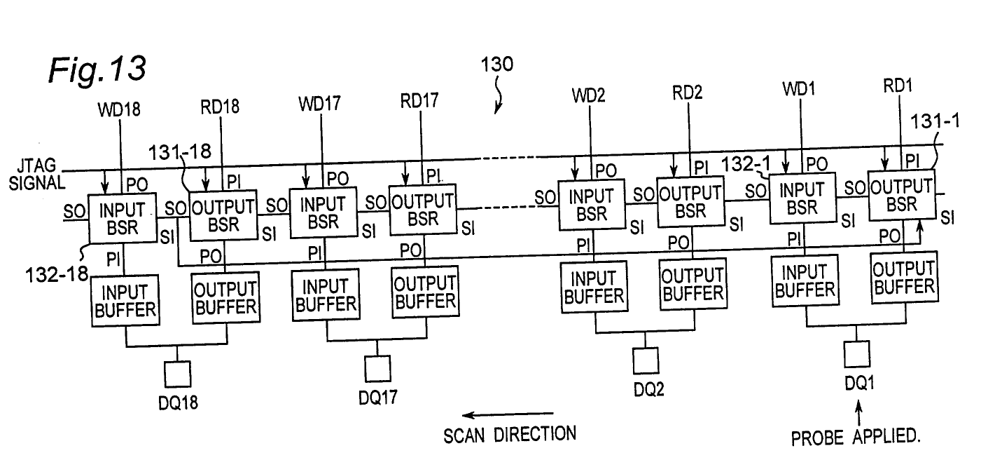

FIG. 13 is a block diagram showing the configuration of another pad peripheral circuit 130 according to embodiment 2. In pad peripheral circuit 130, the probe is applied to data I/O pad DQ1 and the boundary scan register scanning direction is the direction from data I/O pad DQ1 to DQ18. When the scanning is performed in reverse direction or when pads other than data I/O pad DQ1 pad are used for probe application, the configuration shown in FIG. 13 can be used in principle.

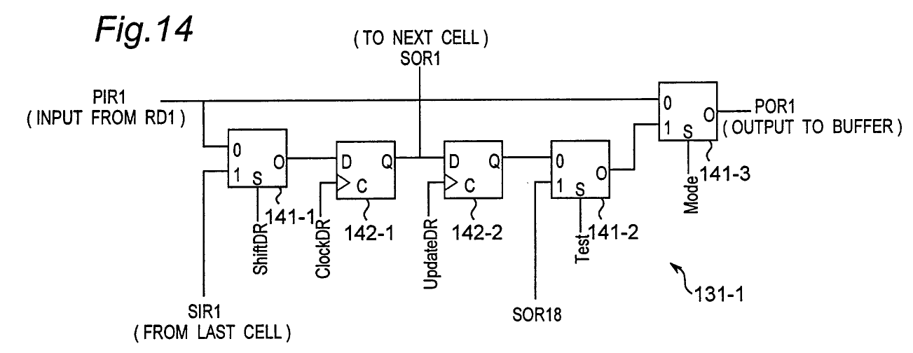

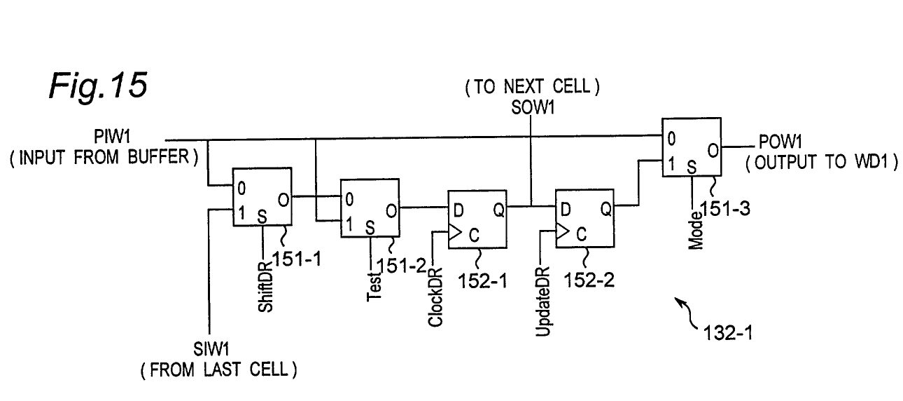

Because in pad peripheral circuit 130, data I/O pad DQ18 serves as the final stage of the shift register, serial output SOR18 of output boundary scan register 131-18 of data I/O pad DQ18 is entered in output boundary scan register 131-1 of data I/O pad DQ1. What must be taken care of is that the configuration of registers 131-1, 132-1 of data I/O pad DQ1 to which the probe is applied differs from the configuration of the boundary scan register shown in FIG. 12. FIG. 14 is a block diagram showing the configuration of output boundary scan register 131-1. In addition, FIG. 15 is a block diagram showing the configuration of input boundary scan register 132-1. In FIG. 14 and FIG. 15, test mode signal Test is a test signal that becomes “H” when the test mode is executed.

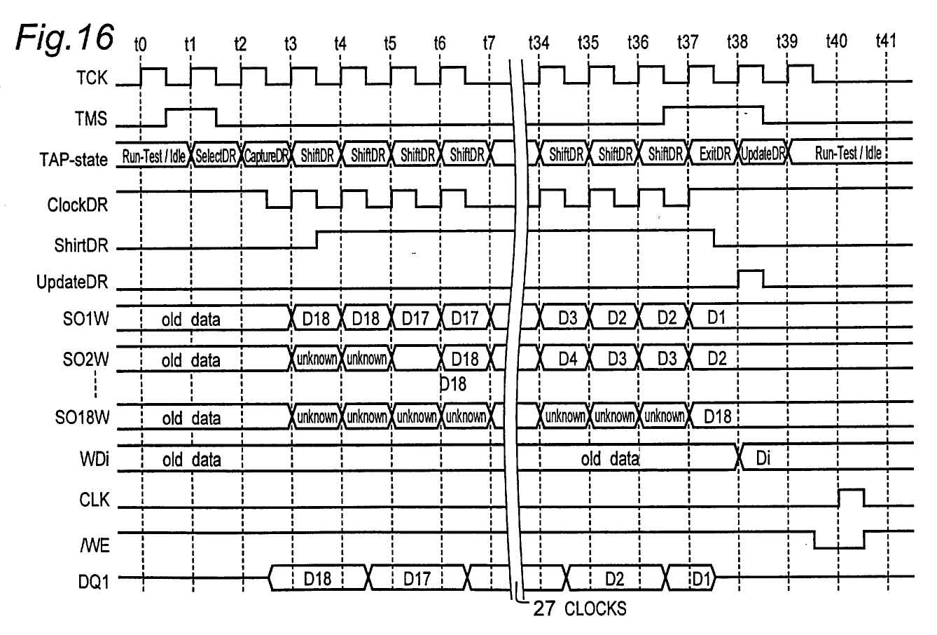

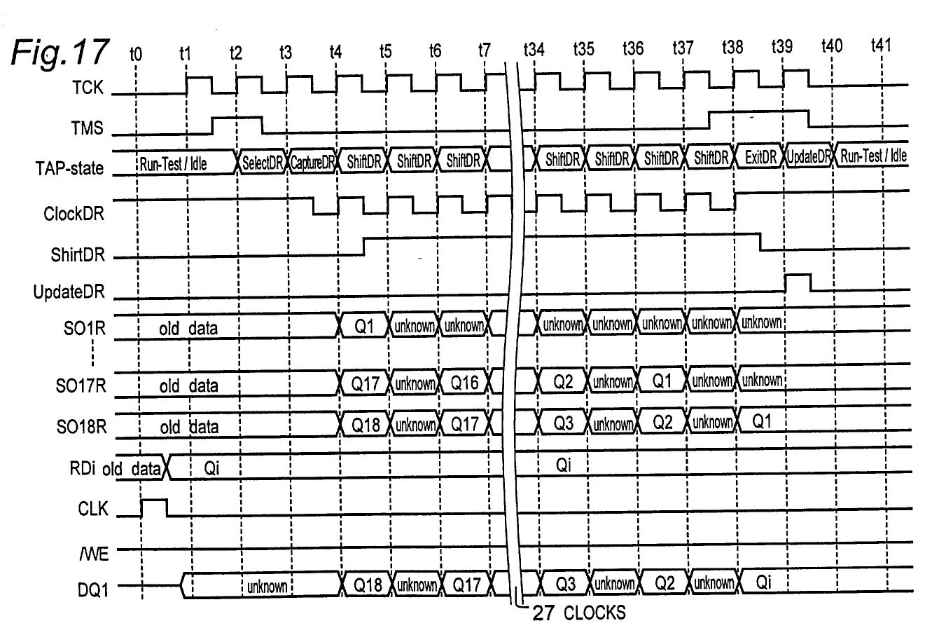

The operation of pad peripheral circuit 130 (FIG. 13) configured as described above will be described referring to FIG. 16 and FIG. 17. In the following description, the configuration same as that of embodiment 1 can be adopted when the data entered from data I/O pad DQ1 at the time of writing is written to all the I/Os simultaneously. Consequently, in the present case, a method for entering the write data serially from data I/O pad DQ1 and giving the data independently to write data buses WD1 through WD18 will be described.

FIG. 16 is a diagram showing test waveforms at the time of writing. In FIG. 16, signal TCK is a test clock of JTAG and signal TMS is a test mode control signal of JTAG. In response to these input signals, TAP-state adopted for JTAG is varied. In accordance with the state of TAP-state, test mode control signals ClockDR, ShiftDR, UpdateDR are generated. The signal Mode is a signal determined in accordance with the JTAG instruction. At the time of test mode in the present embodiment, signal Mode is set to become “H”.

In the initial state, TAP-state is Run-Test/Idle that indicates the test mode and at the same time idling state. Tap-state varies to SelectDR at time t1 and CaptureDR at time t2 as signal TMS is inputted. At time t2-t3 of CaptureDR, signal ClockDR operates and at time t3, input signal D18 to DQ1 pad at this moment is imported into shift register output SO1W of input boundary scan register 132-1 (FIG. 13). Assuming that TAP-state at time t3 is ShiftDR, ShiftDR becomes “H” between time t3 and time t4, enabling shift operation between boundary scan registers. At the same time, signal ClockDR operates and the next data import and shift operation at time t4 are executed.

Between input boundary scan registers, an output boundary scan register exists. Consequently, to data I/O pad DQ1, D18 is given as a dummy data. Thereafter, by giving data D17, D16, . . . , D1 to data I/O pad DQ1 for every 2 clocks of signal TCK with TAP-state kept to ShiftDR, the data can be shifted successively while the data is being inputted.

When at time t37, first input data D18 reaches output SO18W of input boundary scan register 112-18, TAP-state is changed to Exit1DR. At this time, ShiftDR becomes “L” between time t37 and t38 and the shift operation is finished. By changing TAP-state to Update DR at time t38 and operating UpdateDR signal between time t38 and t39, data Di stored in shift register output SORi of each input boundary scan register is written to parallel register output PORi. Because output PORi of the parallel register is connected to each write data bus WDi, data Di is given to write data bus WDi. Under this condition, setting write enable signal /WE to “L” and operating system clock CLK at time t40 executes writing to the memory core. Note that the output enable signal is not shown in FIG. 16, but the output must be disabled by setting it to “H” during writing operation.

FIG. 17 is a diagram showing test waveforms during reading. With write enable signal /WE at time t0 set in the “H” state, system clock CLK is operated. Then, the memory core reading operation is started and read data Q1 is outputted to read data bus RDi of each I/O. Under this condition, signals TCK and TMS are entered, TAP-state is varied from initial state RunTest/Idle to SelectDR at time t2, and then to CaptureDR at time t3. When it is changed to CaptureDR, signal ClockDR is operated and data Qi of read data bus RDi is imported into shift register output SORi of output boundary scan register. In such event, shift register output SOR18 of output boundary scan register 131-18 is inputted to output boundary scan register 131-1. Since signal Test is “H”, the data of data SOR18, that is, Q18, is outputted to data I/O pad DQ1 at time t4.

Thereafter, varying TAP-state to ShiftDR at time t4 brings ShiftDR to “H” between time t4 and t5, enabling the shift operation of the boundary scan register. Furthermore, operating signal TCK in the ShiftDR state shifts data Qi imported and outputted from data I/O pad DQ1 via output boundary scan register 131-18 and output boundary scan register 131-1. Because at time t5, the data of input boundary scan register of I/O 17 is outputted to data I/O pad DQ1, the data becomes the unknown data, but at time t6, the data of output boundary scan register of I/O 17, that is, Q17, is outputted. Thereafter, Q16, Q15, . . . , Q1 are successively outputted to data I/O pad DQ1 every 2 cycles of TCK. After all the read data Q18 through Q1 are outputted, Tap-state is varied successively to Exit1DR, UpdateDR, Run-Test/Idle to return to the initial state. Though not illustrated in FIG. 17, the output enable signal must be set to the enable state while it is set to “L” during read operation. Thereafter, by repeating these, read/write can be executed.

(Embodiment 3)

In embodiment 2, the configuration with input boundary scan register and output boundary scan register separately provided was described (FIG. 11). According to the relevant configuration, the bit length of the shift register increases. Thus, the frequency for scanning the required data increases.

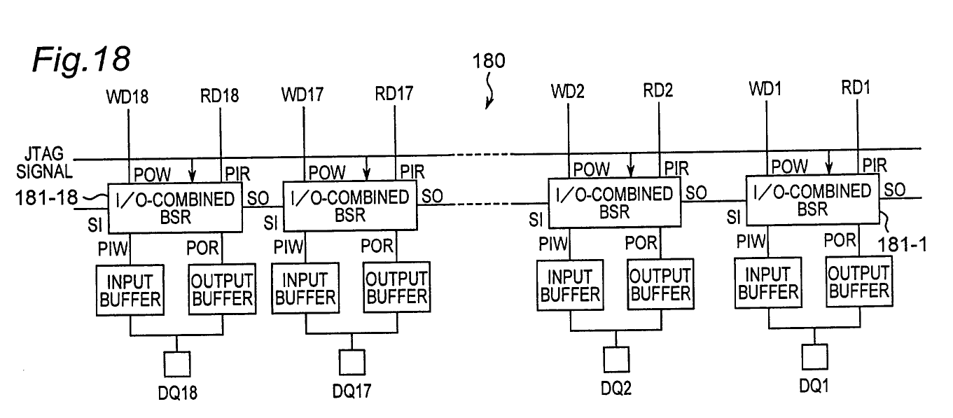

In embodiment 3, description will be made on the configuration with input and output boundary scan registers combined into one. FIG. 18 is a block diagram showing the configuration of pad peripheral circuit 180 with boundary scan register 181-n (n: integer from 1 through 18) used both for input and output. The functions and operations of input-output combined boundary scan register 181-n are the same as those of output boundary scan register 111-n (FIG. 11) at the time of read test, while they are the same as those of input boundary scan register 112-n (FIG. 11) at the time of write test.

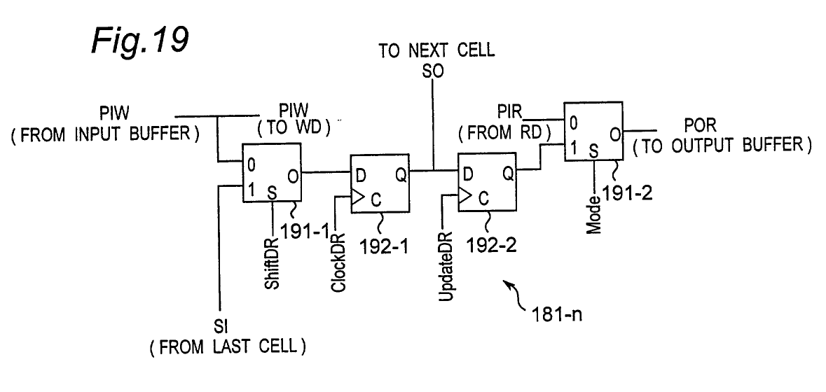

Now, input-output combined boundary scan register 181-n can adopt the simplified configuration shown, for example, in FIG. 19. This configuration can be adopted when the INTEST function, which is a function to send the data from boundary scan register in the direction of the write data bus WD, that is, in the inside direction of the chip, is not required in the JTAG standard. By adopting this configuration, functions of the present invention can be added more efficiently from the viewpoints of both the number of required elements and the packaging area.

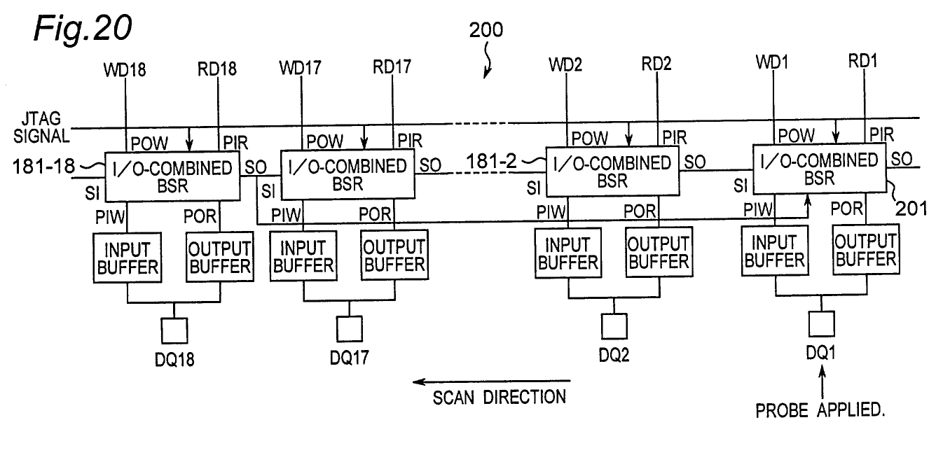

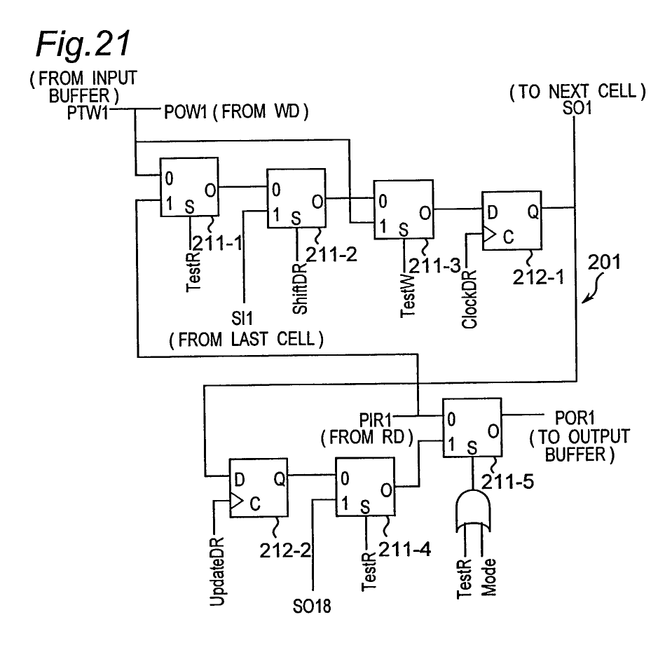

For pad peripheral circuit 130, the input-output combined boundary scan register can be used. FIG. 20 is a block diagram showing the configuration of pad peripheral circuit 200 equipped with I/O-combined boundary scan register. Pad peripheral circuit 200 is equipped with I/O-combined boundary scan register 201 and I/O-combined boundary scan register 181-n (n: integer from 2 to 18). The specific configuration of the I/O-combined boundary scan register is, in principle, the same as that of the boundary scan register shown in FIG. 19. However, the register that corresponds to data I/O pad DQ1 to which the probe is applied must be replaced with the circuit shown, for example, in FIG. 21. FIG. 21 is a bock diagram showing the configuration of I/O-combined boundary scan register 201. In this case, test signal TestW becomes “H” during test-mode write operation and test signal TestR becomes “H” while the test mode is being read.

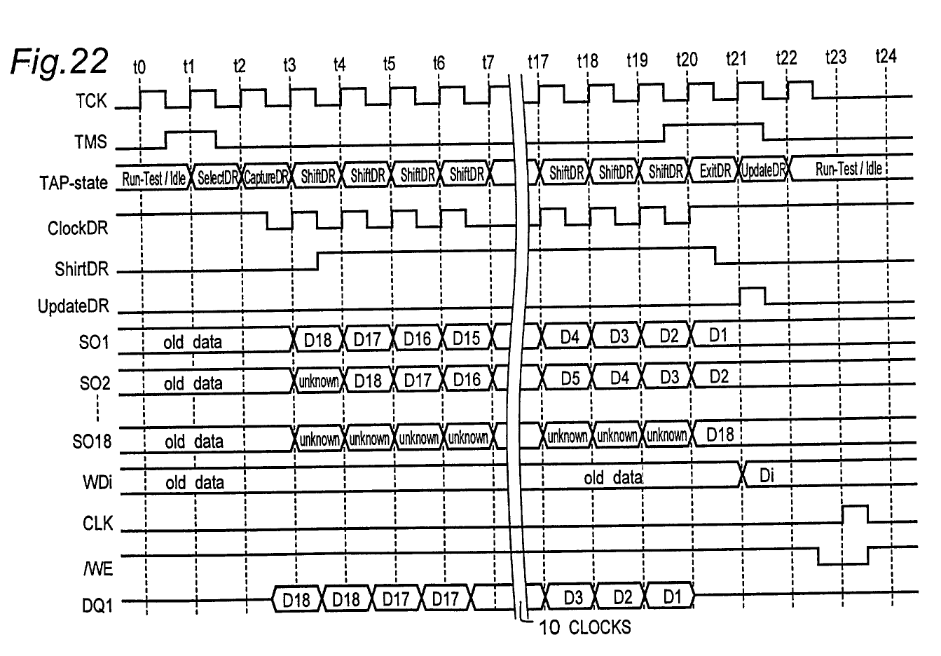

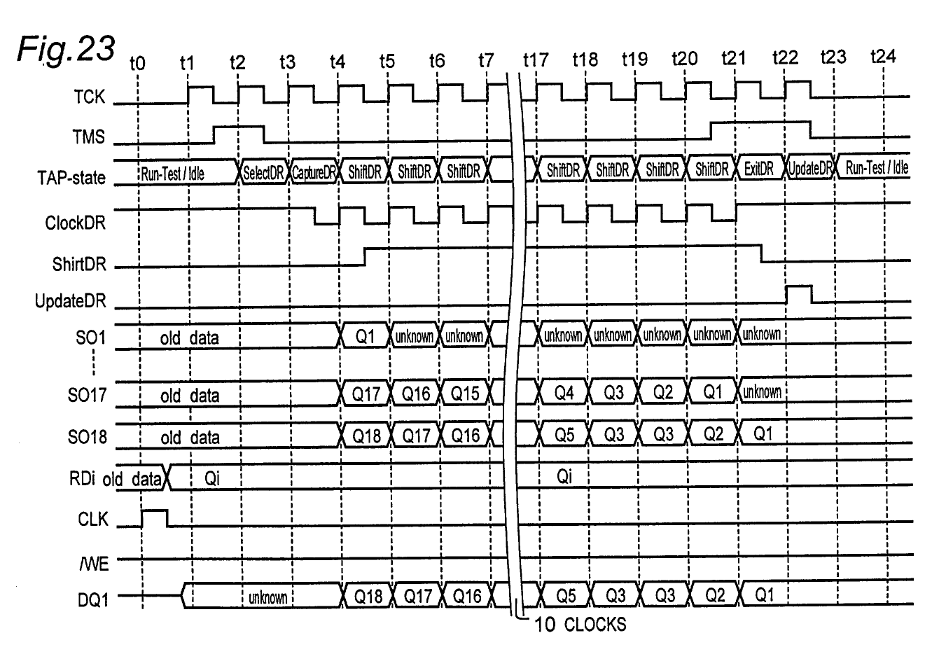

Referring now to FIG. 22 and FIG. 23, the operation of pad peripheral circuit 200 (FIG. 20) configured as described above will be discussed. FIG. 22 is a diagram showing test waveforms at the time of writing. At the time of write operation, first of all, signal TestW is set to “H”, signal TestR to “L”, and signal Mode to “H”. Each external signal shown in FIG. 21 (signal ClockDR, signal ShiftDR, signal UpdateDR, etc.) are entered in the timing as shown in FIG. 22.

The write signal given to data I/O pad DQ1 is entered into I/O-combined boundary scan register 201 (FIG. 20) irrespective of the level of signal ShiftDR because signal TestW is set to “H”. Consequently, every time signal ClockDR operates, the data is shifted. The waveforms of FIG. 22 are, in principle, the same as those of FIG. 16 referred and described in embodiment 2, but since there is no need to insert any extra dummy cycle when the data is shifted, the sift time can be shortened. In addition, since signal Mode is set to “H”, when the state is UpdateDR, data Di is temporarily given to the output buffer of each I/O. However, since data Di is outputted to each I/O pad DQ and is transmitted to write data bus WD as it is, the desired data can be written.

On the other hand, FIG. 23 is a diagram showing test waveforms at the time of reading. At the time of read operation, signal TestR is set to “H”, signal TestW to “L”, and signal Mode to “L”. Each external signal such as signal ClockDR, signal ShiftDR, signal UpdateDR are entered in the timing as illustrated in FIG. 23. The data read into each read data bus is temporarily outputted to each pad because signal Mode is set to “L”, but this is transmitted to parallel input P1 of each boundary scan register from the input buffer as it is. Consequently, the output data can be imported into the shift register when the state is CaptureDR. Note that data I/O pad DQ1 only is used for outputting the serial data. Consequently, the output data cannot be imported through data I/O pad DQ1. Consequently, when signal TestR is “H”, the data bus output is designed to be imported directly to the shift register. In addition, to I/O-combined boundary scan register 201 (FIG. 20), serial output SO18 of I/O-combined boundary scan register 181-18 (FIG. 20) is inputted. In pad peripheral circuit 200 (FIG. 20), even when signal Mode is “L”, if signal TestR is “H”, SO18 is outputted to data I/O pad DQ1.

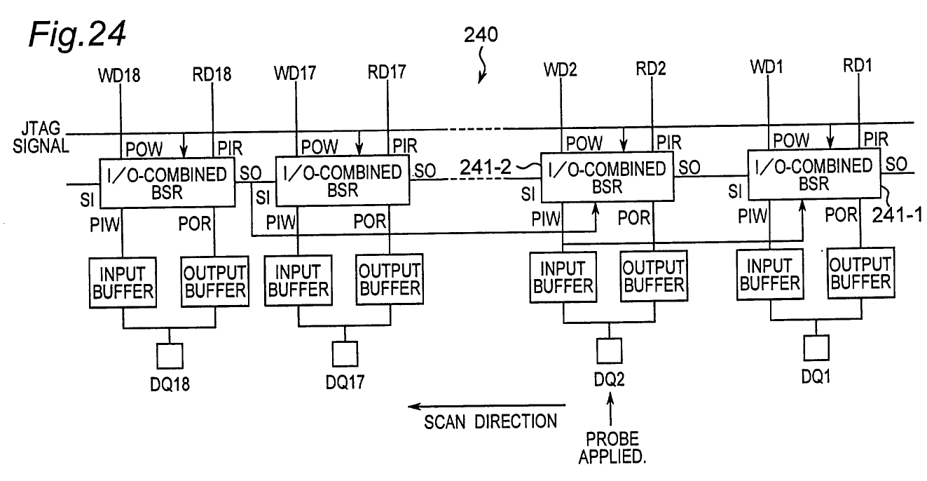

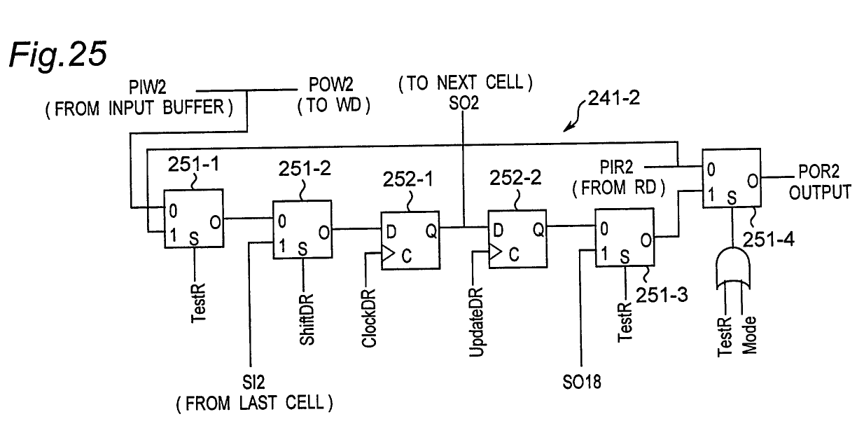

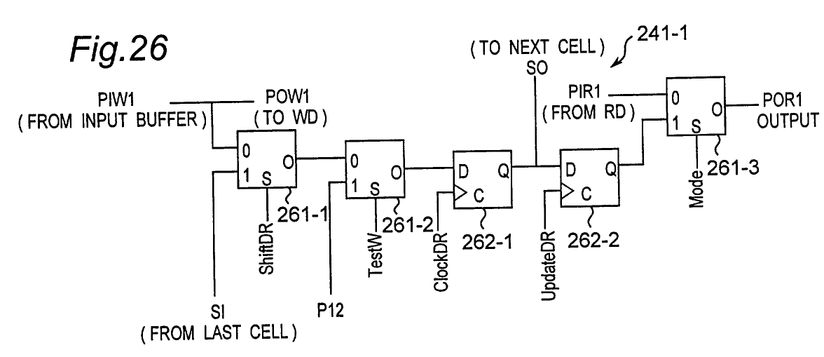

The waveforms of FIG. 23 are, in principle, the same as those of FIG. 17 referred and explained in embodiment 2. However, because, for the waveforms shown in FIG. 23, no unwanted data is inserted during serial output, all the data can be read in a short shift time. Note that, in this case, the pad to which the probe is applied is data I/O pad DQ1. However, any pad may be used for the pad to which the probe is applied. For example, FIG. 24 is a block diagram showing the configuration of pad peripheral circuit 240 when data I/O pad DQ2 is used for the pad to which the probe is applied. What must be noted is that the configuration of boundary scan register 241-2 corresponding to data I/O pad DQ2 to which the probe is applied and that of boundary scan register 241-1 at the head of the scanning direction must be partly modified. FIG. 25 is a block diagram showing an example of the configuration of boundary scan register 241-2, while FIG. 26 is a block diagram showing an example of the configuration of boundary scan register 241-1. By modifying as described above, it is possible to allow the circuit to operate in the same manner as pad peripheral circuit 200 (FIG. 20).

According to embodiments 1 through 3 described so far, the wafer test can be carried out by applying the probe to one specific data I/O pad only and inputting and outputting the data of a plurality of other pads from the pad. Now, by limiting the probe application in the wafer test to two sides only with the pad (pad P) other than DQ pads provided, the pad intervals can be reduced from the conventional ones.

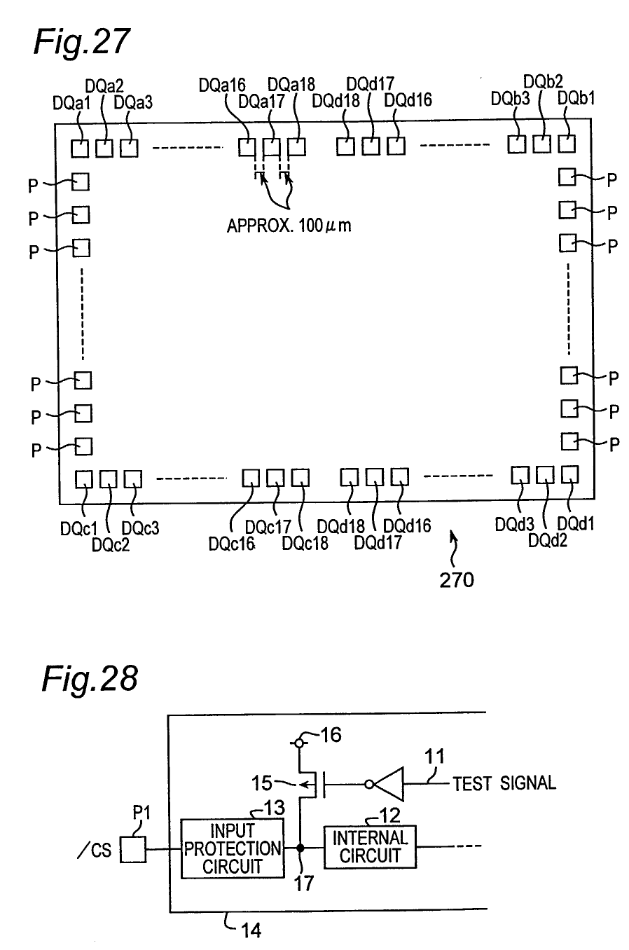

FIG. 27 is a top view of chip 270 of the semiconductor storage unit with pad intervals reduced. In general, pad arrangement conditions based on the wafer test restrictions are more stringent than the conditions based on the assembly restrictions. That is, by the wafer test restrictions, the pad intervals must be increased. Specifically, when the wafer test is carried out, about 125 μm is required for pad intervals. On the other hand, when the assembly is carried out, about 100 μm is required for pad intervals. This means that for the wafer test, pad intervals must be increased by about 25 μm.

Consequently, if conditions are imposed at the time of wafer test that the probe is not applied to pads on the edges of two sides except for the marginal two pads respectively, with data I/O pad DQ collected, the pad intervals on the two sides can be made about 100 μm as shown in FIG. 27. Thus, the intervals can be narrowed by about 25 μm per 1 pad, the length of the pad region can also be shortened. The address/control pad P intervals are held to about 125 μm as conventional, because control signals must be given even during the test. Consequently, the data I/O pad DQ intervals are narrower than those of the address/control pad P. Since intervals of data I/O pad DQ can be narrowed, the chip size can be reduced.

(Embodiment 4)

In embodiment 1, referring to FIG. 5 and FIG. 6, a method for giving the same data to pad 18 in parallel and writing the data in I/O in parallel was described. In the case of a test mode in which the data is written in parallel and thereafter the data is read serially, all the bits are written at the same value and the same data is read continuously. When the same data is continuously read, it is unable to judge from the outside whether the inside is in the normal serial read test condition or the inside is not in the serial read test condition and the same bit data is simply read.

Therefore, in embodiment 4, description will be made on the configuration and the operation that can confirm from the chip outside that the operation of test mode of writing the data in parallel and reading the data serially is properly taking place. By further incorporating the configuration of embodiment 4 into the configuration of embodiments 1 through 3, a still more improved chip for the semiconductor storage unit can be provided.

FIG. 28 is a block diagram showing the configuration of control circuit 14 according to embodiment 4. Control circuit 14 is connected to control pad P1 with low-level or high-level control signals (control voltages) applied and chip 10 (FIG. 1) is activated when control voltage is of a low level. To describe more specifically, the control circuit 14 comprises internal circuit 12, input protect circuit 13, micro-current generating circuit 15, and power supply 16. Internal circuit 12 and input protection circuit 13 are component elements generally provided for the control circuit. First of all, input protection circuit 13 protects internal circuit 12 and other circuit element(s) when control voltage applied to control pad P1 is excessively high. Internal circuit 12 is activated when the control voltage applied to control pad P1 is of a low level and starts the operation of chip 10 (FIG. 1). Because whether chip 10 (FIG. 1) is activated or not is selected according to the voltage applied to control pad P1, control pad P1 is also called chip select terminal (CS).

Features of control circuit 14 of embodiment 4 lie in the configuration for detecting TEST signal which achieves a high level at the time of test mode. In other words, micro-current generating circuit 15 and power supply 16 are added. TEST signal 11 is the same as TEST signal shown, for example, in FIG. 2. If it is able to detect whether TEST signal 11 that achieves a high level at the time of test mode is applied or not, it is able to confirm that the inside of chip 10 (FIG. 1) is in the test condition.

The micro-current generating circuit 15 is a PMOS transistor, which makes “ON” operation when TEST signal 11 is on the high level and allows ON current to flow by connecting an inverter to the gate. ON current is sufficiently small and is detected at control pad P1 via node 17 and input protection circuit 13. Power supply 16 supplies electric power and at the time of “ON” operation of micro-current generating circuit 15, the sufficiently small ON current is allowed to flow as described above. The reasons for making ON current small are as follows. In the case of detecting the presence of TEST signal 11, It is premised that chip 10 (FIG. 1) is activated. Consequently, to node 17 and internal circuit 12, low-level control voltage must be applied. However, when the ON current is large, high-level voltage is applied to node 17, and low-level control voltage is unable to be applied to internal circuit 12. With the foregoing reasons, the ON current must be minute.

Now, the operation of control circuit 14 is described. When the inside of chip 10 (FIG. 1) enters the test mode, TEST signal 11 achieves a high level and micro-current generating circuit 15 is turned on. When the low level signal is applied to input terminal 14 and the chip is activated, micro-current flows from power supply 16 to control pad P1 via micro-current generating circuit 15, node 17, and input protection circuit 13. When the test mode is not achieved, that is, when TEST signal 11 is of a low level, micro-current generating circuit 15 is kept off, and no current flows in micro-current generating circuit 15. Consequently, connecting a measuring apparatus for detecting the current to control pad P1 and detecting the micro-current from control pad P1 enables judgment of the presence of application of TEST signal 11, and therefore, it is possible to detect from the outside whether the chip inside enters the test mode or not.

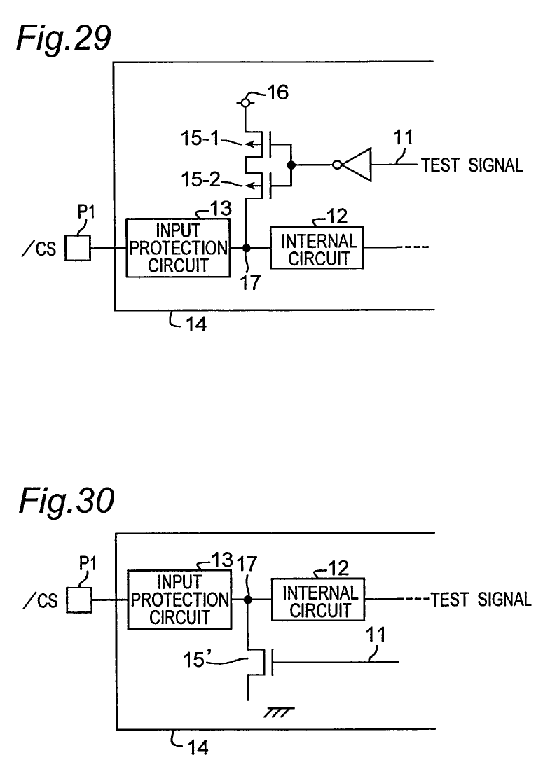

The voltage drop caused by micro-current generating circuit 15 must be kept sufficiently small. To achieve this, it is effective to make the ON current as small as possible. For example, the ON current can be made small by reducing the channel width of PMOS transistor of FIG. 28 that forms the micro-current generating circuit 15 or making the channel length larger. Or, the ON current may be prevented to flow smoothly by increasing the resistance. FIG. 29 is a block diagram showing another configuration of micro-current generating circuit 15. In this case, two PMOS transistors 15-1 and 15-2 are connected in series. This configuration is the same as that of control circuit 14 shown in FIG. 28. According to this configuration, the resistance increases and the current becomes difficult to flow and voltage drop generated in micro-current generating circuit 15 decreases.

In the present embodiment, description was made on an example in which chip 10 (FIG. 1) is activated when low-level control voltage is applied to control pad P1 and the presence of TEST signal 11 is detected in such condition. However, needless to say, it may be configured to activate chip 10 (FIG. 1) when high-level control voltage is applied to control pad P1.

FIG. 30 is a block diagram showing the configuration when micro-current generating circuit 15′ is installed to control circuit 14 to be activated by the high-level control voltage. In control circuit 14 shown in FIG. 28, the PMOS transistor as micro-current generating circuit 15 has the source connected to power supply 16 and the drain to node 17. On the other hand, in FIG. 30, micro-current generating circuit 15′ is an NMOS transistor and the source is connected to node 17 and drain is grounded. In this case, when TEST signal 11 is of a high level, micro-current generating circuit 15 is turned on and sufficiently small ON current flows.

The operation of control circuit 14 of FIG. 30 is described. When chip 10 (FIG. 1) enters the test mode, TEST signal 11 becomes a high level and micro-current generating circuit 15 is turned on. At this time, the high-level control voltage is applied to control pad P1 and when chip 10 (FIG. 1) is in the activated state, the micro-current flows from control pad P1 to the reference power supply via micro-current generating circuit 15′. When TEST signal 11 is of a low level and is not in the test mode, micro-current generating circuit 15′ is kept off, and no current flows even when the high-level control voltage is applied to control pad P1. Consequently, by connecting a measuring apparatus that can detect the current to control pad P1 and detecting the micro-current that flows from the measuring apparatus to control pad P1, the presence of application of TEST signal 11 can be judged and consequently, it is possible to detect from the chip outside whether the chip is in the test mode operation or not.

(Embodiment 5)

In embodiment 4, the presence of TEST signal and whether the chip inside is in the test mode or not are detected by detecting the micro-current of control pad P1 (FIG. 28). In embodiment 5, in addition to this operation, the description will be made on a configuration that can detect from the outside whether the clock signal for sequentially shifting the data is properly generated when the data is transmitted serially.

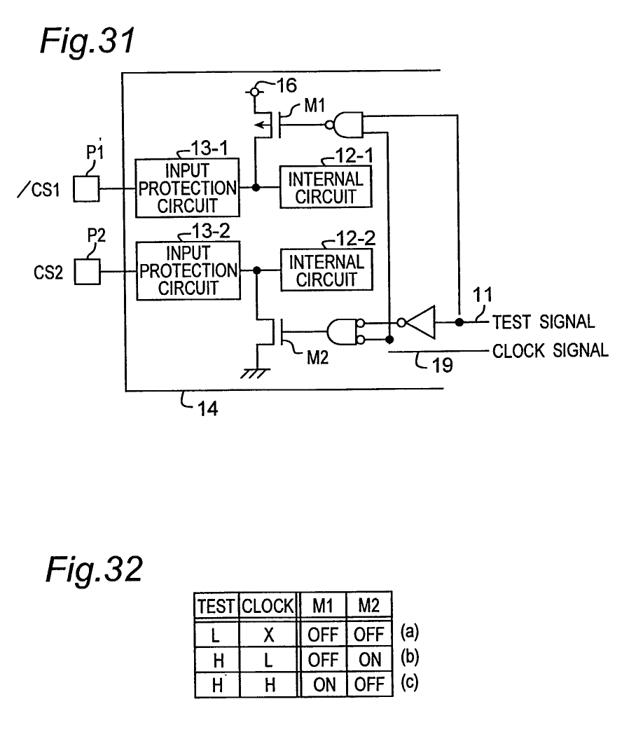

FIG. 31 is a block diagram showing the configuration of control circuit 14 according to embodiment 5. In this control circuit 14, not only TEST signal 11 but also CLOCK signal 19 for sequentially shifting the data at the time of serial transmission are detected. Internal circuit 12-1 has functions same as those of internal circuit 12 (FIG. 28) and are activated when control voltage of low level signal is applied to control pad P1. Internal circuit 12-2 is activated when control voltage of high-level signal is applied to control pad P2. Input protection circuits 13-1 and 13-2 have functions same as those of input protection circuit 13 (FIG. 28) and restricts the size of voltage applied to internal circuits 12-1 and 12-2 and protects internal circuits 12-1 and 12-2.

Micro-current generating circuits M1 and M2 are PMOS transistor and NMOS transistor that generate micro-current to control pads P1 and P2, respectively. To the gate of micro-current generating circuit M1, the results of NAND operation of TEST signal 11 and CLOCK signal 19 are entered. To the gate of micro-current generating circuit M2, results of AND operation of TEST signal 11 and reversed CLOCK signal 19 are entered.

Referring now to FIG. 32, operations of control circuit 14 will be described. FIG. 32 is a truth value table that indicates the relationship between TEST signal 11 and reversed CLOCK signal 19 as well as operations of micro-current generating circuits M1 and M2.

As shown in (a) of FIG. 32, when the unit is not in the test mode, that is, when TEST signal 11 (FIG. 31) is of a low level (L), micro-current generating circuits M1 and M2 are turned off. This always holds for irrespective of the conditions of CLOCK signal 19 (FIG. 31). Consequently, in control pads P1 and P2, no micro-current is detected.

When the unit enters the test mode, TEST signal 11 (FIG. 31) becomes a high level (L). In such event, if CLOCK signal 19 (FIG. 31) is of a low level, as shown in (b) of FIG. 32, micro-current generating circuit M2 only is turned on. Micro-current generating circuit M1 is kept turned off. Consequently, micro-current is detected in control pad P2 only. On the other hand, when CLOCK signal 19 (FIG. 31) is also of a high level, as shown in (c) of FIG. 32, micro-current generating circuit M1 only is turned on and micro-current generating circuit M2 is kept turned off. Consequently, micro-current is detected in control pad P1 only.

As understood from the foregoing description, when micro-current is detected from control pad P1 only, both TEST signal 11 (FIG. 31) and CLOCK signal (FIG. 31) are of a high level, which means that signals are correctly applied. In addition, when micro-current is detected only from control pad P2, only TEST signal 11 (FIG. 31) is of a high level and CLOCK signal 19 (FIG. 31) is of a low level. Consequently, in such event, it means that TEST signal 11 (FIG. 31) only is correctly applied and CLOCK signal 19 (FIG. 31) is not applied. When no micro-current is detected from control pads P1 and P2, it means that TEST signal 11 (FIG. 31) is not applied. Consequently, it is possible to judge externally the test mode signal condition and clock signal condition at the time of test mode from the measuring device installed outside for detecting current.

(Embodiment 6)

In embodiment 5, the configuration that could confirm operations of test mode signal and clock signal by the use of a plurality of terminals (control pads P1 and P2). In embodiment 6, using a single control pad, the configuration that could confirm them will be described.

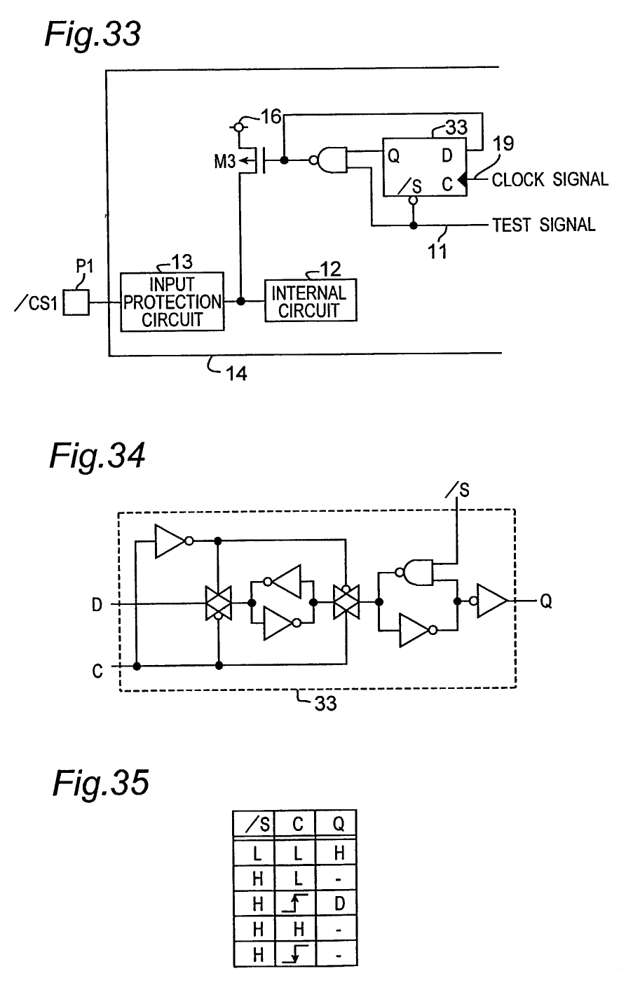

FIG. 33 is a block diagram showing the configuration of control circuit 14 according to embodiment 6. Control circuit 14 in the present embodiment has D flip-flop 33 to the control circuit of FIG. 28 and the conditions of TEST signal 11 and CLOCK signal 19 are intended to be detected. To the gate of micro-current generating circuit M3, results of NAND operation of Q output of D flip-flop 33 and TEST signal 11 (FIG. 31) are entered. The NAND operation results are fed back as an input to D terminal of D flip-flop 33. Since other configurations are same as those of the control circuit of FIG. 28, the description will be omitted.

Now, new configurations added to control circuit 14 will be described. Control circuit 14 is equipped with D flip-flop 33 with set terminals. D flip-flop 33 has a data (D) terminal and a clock (C) terminal and is a circuit that takes in data values of D terminal entered in a significant edge of C terminal as a state and holds the condition until the next significant edge for clock entry is received. In the present embodiment, the significant edge is a rising edge. However, the significant edge may be a trailing edge. Even if the value of D terminal is varied, output Q is not varied until the next clock is activated. When the next edge is received, the value of D terminal appears at output Q. FIG. 34 is a block diagram showing a specific configuration of D flip-flop 33. Because the configuration of this kind of D flip-flop 33 is known to every one, the specific description will be omitted. FIG. 35 is a truth value table showing the relationship between the input and the output of D flip-flop 33. The symbol “−” of the Q-terminal column indicates that it is not changed from the previous condition. To describe the operation of D flip-flop 33 (FIG. 34), when set terminal (/S) and clock terminal C are of low level L, Q terminal changes to high level H. On the other hand, when set terminal (/S) is of high level H, Q terminal changes to the data terminal D value when clock terminal C is activated from low level to high level and Q terminal does not change in any other cases.

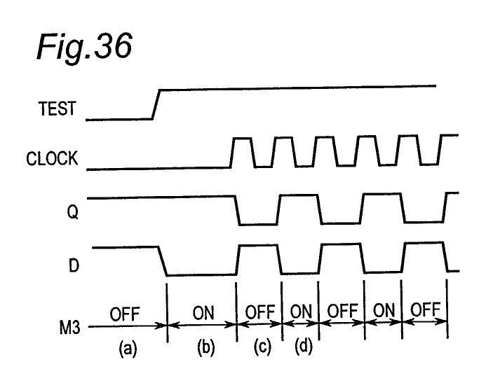

Now, operations of control circuit 14 including the foregoing D flip-flop 33 will be described. FIG. 36 is a timing chart showing operations of control circuit 14 (FIG. 33). It is understood that various signals inside control circuit 14 vary in accord with the conditions of TEST signal and CLOCK signal. When they are not in the test mode, as shown in the timing of (a), both TEST signal and CLOCK signal are in the low level. Consequently, since as a result of NAND operation, the gate of micro-current generating circuit M3 becomes a high level, micro-current generating circuit M3 is turned off. That is, no micro-current is detected in control pad P1.

When the unit enters the test mode, TEST signal becomes a high level. As shown in the timing of (b), when TEST signal of a high level is entered in set (S) terminal, the NAND operation results become a low level because the Q terminal output is similarly of a high level. Consequently, micro-current generating circuit M3 is turned on. That is, when the micro-current is detected in control pad P1 in this timing, it is able to judge that the unit enters the test mode. Then, as shown in the (c) timing, by entering CLOCK signal of a high level, micro-current generating circuit M3 is turned off. Consequently, no micro-current is detected at control pad P1. When no micro-current is detected in control pad P1 in this timing, it is judged that CLOCK signal pulses are properly generated.

Then, by re-entering CLOCK signal, the timing shifts to condition (d). In this timing, micro-current generating circuit M3 is turned on. That is, if the micro-current is detected again in this event, it is able to be judged that CLOCK signal pulses are normally generated. Hereinafter, every time clock signal 41 is entered, conditions (c) and (d) are repeated, and by judging whether micro-current could be detected or not every time the signal is inputted, it is possible to confirm from the outside whether CLOCK signal is properly generated or not.

As described above, according to the inventions described in embodiment 4 through 6, in a semiconductor storage unit equipped with the test mode that writes data in parallel and reads data in series, it is possible to confirm from the chip outside whether the operation in the test mode condition correctly takes place or not. In addition, it has been described that embodiments 4 through 6 could be applied to embodiments 1 through 3. However, chips that carry out chip tests by using TEST signal and CLOCK signal as described above, can detect the presence of TEST signal and/or the present of CLOCK signal by the use of the configuration of embodiments 4 through 6.

Throughout embodiments 4 through 6, a control pad (chip select terminal) is mentioned as an input terminal of chip 10 (FIG. 1). However, if no trouble occurs in the circuit operation even when the potential for detecting the micro-current is inputted, other input terminals may be used.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A semiconductor storage unit with a plurality of data pads which input and output data arranged on predetermined two sides and a plurality of control pads which input and output control data arranged on other two sides, comprising:
a plurality of test circuits connected in series, each of which is connected to a corresponding data pads of the plurality of data pads and has a register circuit which holds and outputs inputted data based on a test signal; and
a plurality of storage elements, each of which stores data and is connected to a corresponding test circuit of the plurality of test circuits,
wherein at the time of testing the semiconductor storage unit, the plurality of storage elements store the data inputted from a predetermined data pad of the plurality of data pads and transmitted to a predetermined test circuit, and
wherein the register circuit reads the data stored in the corresponding storage element and outputs the data from the predetermined data pad via other register circuit of the plurality of test circuits connected in series.

2. The semiconductor storage unit according to claim 1, wherein the predetermined test circuit receives data for each of the plurality of test circuits entered serially from a specific data pad.

3. The semiconductor storage unit according to claim 2, wherein the predetermined data pad comes in contact with any of the other two sides of the plurality of data pads.

4. The semiconductor storage unit according to claim 1, wherein the specific data pad exists in the plural number, and
wherein the predetermined test circuit receives data for each of the plurality of test circuits entered in parallel from the specific data pad.

5. The semiconductor storage unit according to claim 4, wherein each of the plurality of storage elements stores data for each corresponding test circuit, and
wherein the data read by the register circuit of the corresponding test circuit is serially outputted from the specific data pad.

6. The semiconductor storage unit according to claim 5, wherein the specific data pad comes in contact with any of the other two sides of the plurality of data pads.

7. The semiconductor storage unit according to claim 4, wherein the plurality of test circuits are JTAG boundary scan register circuits.

8. The semiconductor storage unit according to claim 7, wherein the JTAG boundary scan register circuit takes in the data from the storage element outputted to the predetermined data pad.

9. The semiconductor storage unit according to claim 7, wherein the JTAG boundary scan register circuit provides the storage element with set written data after it is outputted to the specific data pad.

10. The semiconductor storage unit according to claim 4, wherein an interval between two of the plurality of data pads are narrower than that of the plurality of control pads.

11. A semiconductor storage unit comprising:
a plurality of data pads which are arranged on predetermined two sides and which input and output data; a plurality of control pads which are arranged on other two sides different from the predetermined two sides and which input and output control data; and a control circuit which controls operations of the semiconductor storage unit,
wherein the control circuit comprises an internal circuit, connected to at least one of the control pads, which operates the semiconductor storage unit based on the control signal applied to the control pad, power supply which supplies current, and a current generating circuit which feeds the current supplied from the power supply to at least one of the control pads when a test signal is of the test mode level.

12. The semiconductor storage unit according to claim 11 further comprising:
register circuits, each of which holds and outputs data entered based on the test signal; a plurality of test circuits connected in series; and a plurality of storage elements which stores data,
wherein at the time of testing, the plurality of storage elements store the data entered from a specific data pad of the plurality of data pads and transmitted to a specific test circuit, and the register circuits reads the data stored in the corresponding storage element based on a clock signal, and outputs the data from the specific data pad via other register circuit of the plurality of test circuits connected in series, and
the current generating circuit feeds the current supplied from the power supply to at least one of the control pads according to the input of edge of the clock signal when the test signal is of the test mode level.

13. The semiconductor storage unit according to claim 12, wherein the current generating circuit feeds the current supplied from the power supply to at least one of the control pads according to the input of one of a rising edge and a trailing edge of the clock signal.
